(19) United States
(12) Patent Application Publication
(10) Pub. No.: US 2006/0015797 A1
(43) Pub. Date: Jan. 19, 2006

(54) Information reproducing method and information recording reproducing apparatus with maximum likelihood decoding

(75) Inventor: Yasuyuki Miyaoka, Yokohama-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/131,194

(22) Filed: May 18, 2005

(30) Foreign Application Priority Data
May 18, 2004 (JP) 2004-147855 (PAT.

(51) Int. Cl. H03M 13/03

(52) U.S. Cl. 714/794

(57) ABSTRACT

To provide a regenerative signal evaluation method in which the transition of polarity of a regenerative signal, or the change of polarity in a record mark sequence, is dealt with employing an index in correlation with an error ratio of binarization result by a maximum likelihood decoding. The method comprises detecting a recording series on a state transition path having a certain Euclid distance by the maximum likelihood decoding corresponding to a change of polarity of record code in the recording series, acquiring a likelihood difference between the most probable state transition path and the secondly probable state transition path from branch of state transition paths to merge of state transition paths in the detected recording series, and conducting a statistical processing for the likelihood difference individually corresponding to the change of polarity in the recording series to evaluate the quality of reproducing signal.

### BACKGROUND OF THE INVENTION

1. Field of the Invention

The present invention relates to an information reproducing method and an information recording reproducing apparatus employing the maximum likelihood decoding such as partial response and Viterbi decoding.

2. Related Background Art

In recent years, as various kinds of information such as image information and sound information are digitized, the amount of digital information is greatly increasing. Along with this, the development of optical disks and optical disk units suitable for larger capacity and higher density has progressed. Along with the evolution of digital information of higher density, it is required that the parameters involved in recording and reproducing the information are controlled at higher level. Accordingly, it has been getting more important in recent years to evaluate the quality of reproducing signal.

The evaluation of regenerative signal is used to adjust the conditions of an optical disk unit so that the quality of reproducing signal may be best in recording and reproducing the information, for example. Therefore, it is asked to evaluate the quality of reproducing signal more precisely and in a shorter time.

Conventionally, in the evaluation of optical disk or optical disk unit, the jitter or bit error rate (BER) is employed. In recent years, the PRML (Partial Response Maximum Likelihood) method that is maximum likelihood decoding is employed as a data detection method for making higher density recording.

An evaluation apparatus which is suitable for this PRML method was disclosed in Japanese Patent Application Laid-Open No. H10-021651, for example. A regenerative signal evaluation method for use with an information recording reproducing apparatus such as the optical disk which was described in the above patent will be described below.

First of all, in the conventional signal evaluation apparatus, the regenerative signal is decoded by a Viterbi decoding method. A (1, 7) RLL code in which the minimum run length is limited to 1 as a modulation code for use is adopted, and PR (1, 2, 2, 1) is adopted as the PRML method. The state S(k) which depends on a record bit string b(k) at the data distinction point k takes six states of S0, S1, S2, S3, S4 and S5, as listed in Table 1 below.

TABLE 1

| Record bit [b(k-2), b(k-1,) b(k)] | | | State S(k) |
|---|---|---|---|
| 0 | 0 | 0 | S0 |
| 0 | 0 | 1 | S1 |
| 0 | 1 | 1 | S2 |
| 1 | 1 | 1 | S3 |
| 1 | 1 | 0 | S4 |
| 1 | 0 | 0 | S5 |

Each state transits to the next state according to the next record bit. This state transition is called a branch. The relationship between the record bit and the state transition is listed in Table 2. FIG. 1 is a state transition diagram, and FIG. 2 is a trellis diagram.

TABLE 2

| | | | | | State | | Output | |
|---|---|---|---|---|---|---|---|---|
| | Record bit | | | | transition | | (Expected value) | Branch metric value |
| Branch | b(k-3) | b(k-2) | b(k-1) | b(k) | S(k-1) | S(k) | y(k) | (z(k) − y(k))² |
| a | 0 | 0 | 0 | 0 | S0 | S0 | −3 | bma (k) = (z(k) + 3)² |
| b | 1 | 0 | 0 | 0 | S5 | S0 | −2 | bmb (k) = (z(k) + 2)² |
| c | 0 | 0 | 0 | 1 | S0 | S1 | −2 | bmc (k) = (z(k) + 2)² |
| d | 1 | 0 | 0 | 1 | S5 | S1 | −1 | bmd (k) = (z(k) + 1)² |
| e | 0 | 0 | 1 | 1 | S1 | S2 | 0 | bme (k) = (z(k) − 0)² |
| f | 0 | 1 | 1 | 1 | S2 | S3 | 2 | bmf (k) = (z(k) − 2)² |
| g | 1 | 1 | 1 | 1 | S3 | S3 | 3 | bmg (k) = (z(k) − 3)² |
| h | 0 | 1 | 1 | 0 | S2 | S4 | 1 | bmh (k) = (z(k) − 1)² |
| i | 1 | 1 | 1 | 0 | S3 | S4 | 2 | bmi (k) = (z(k) − 2)² |
| j | 1 | 1 | 0 | 0 | S4 | S5 | 0 | bmj (k) = (z(k) − 0)² |

As described above, the (1, 7) RLL code in which the minimum run length is limited to 1 as a cord for use is employed herein. That is, since the minimum run length is limited to 1, the number of branches is 10, including a, b, c, d, e, f, g, h, i and j.

In the PR(1, 2, 2, 1), the regenerative signal level is decided by the record bit string of four bits, whereby the expected value, or the regenerative signal level in the ideal waveform without noise, is listed as expected value y(k) in Table 2. Herein, the minimum value of the regenerative signal level in the ideal waveform is shown as −3 and the maximum value as 3.

Herein, the branch metric value of each branch at the data distinction point k
(z(k)−y(k) )²
is computed. Where z(k) is the regenerative signal level at the data distinction point k, and y(k) is the expected value of the regenerative signal level. Thus, the branch metric value is the square of a difference between the regenerative signal level and its expected value, which means a square error of the regenerative signal level to the expected value. The branch metric value is employed to decide which branch to select, when two branches joins in a certain state. A series of branches is called a path, and a series of selected branches is called a surviving path.

Herein, supposing that the total value of branch metric value for the surviving path in each state at the k−1 data distinction point is m(k−1), the total value of branch metric value at the data distinction point k is obtained by adding the branch metric value bm(k) at the data distinction point k to m(k−1). Since the branch metric value means the square error as described above, the total value is the sum of errors.

Hence, the branch with the smaller value of
m(k−1)+bm(k)
is selected.

For example, there are two branches in which the state at the data distinction point k is S0, including branch a transiting from S0 to S0 and branch b transiting from S5 to S0, as seen from Table 2. Supposing that the total values of branch metric for the branches a and b are mS0(k−1) and mS5(k−1), and their branch metrics are bma(k) and bmb(k), the total values mS0(k)a and mS0(k)b of the branch metric a and branch metric b at the data distinction point k are given by the following Formula (6).
mS0(k)a=mS0(k−1)+bma(k)
mS0(k)b=mS5(k−1)+bmb(k) Formula (6)

Further, by comparing mS0(k)a and mS0(k)b, the branch having a smaller value is selected. The above procedure is the principle of deciding the regenerated series by the Viterbi decoding that is the maximum likelihood decoding.

The record code sequence on the selected surviving path is regenerated as the information regenerated signal sequence. Regarding the quality of reproducing signal by the maximum likelihood decoding, it is said that as the total value of branch metric value in selecting the path by the maximum likelihood decoding is closer to that in the ideal state, the quality of reproducing signal is better. Thereby, the quality of reproducing signal can be evaluated according to the regeneration method of maximum likelihood decoding by evaluating a difference in the metric value through comparison and selection of branch metrics at the path junction point.

Herein, when the correct state at the data distinction point k is S0, and the correct transition is a, the arithmetic operation
Δm(k)=mS0(k)b−mS0(k)a
is performed, in which Δm(k) is called a metric difference.

Also, when the correct state at the k-th sample time is S0, and the correct transition is b, the metric difference Δm(k) is given by
Δm(k)=mS0(k)a−mS0(k)b

That is, the total value of branch metric for the correct transition is subtracted from the total value of branch metric for the wrong transition.

As a result of decoding, if the selected branch is correct branch, the metric difference Δm(k) is a positive value, but if the wrong branch is selected, the metric difference is a negative value.

Also, the distribution width of metric difference value is different depending on the Euclid distance between record code sequences on the paths from the branch of state transition paths to merge of state transition paths.

For example, in the PR(1, 2, 2, 1), in which the minimum Euclid distance is 10, when the regenerative signals in the ideal state are obtained in two record code sequences having the minimum Euclid distance, the metric difference value is “10” because the metric value on the correct path is “0” and the metric value on the wrong path is “10” at the merge point of paths.

Similarly, the ideal value of the metric difference value in the ideal state is changed with the Euclid distance. Accordingly, when the metric difference value is evaluated for all the regenerative code series, the metric difference value is varied with the Euclid distance up to the branch point of paths before joining of the paths, whereby the statistical distribution of metric difference is different from the normal distribution, making the correlation between the statistical processing with metric difference and the error ratio smaller.

Hence, it is desired that the recording series for evaluating the metric difference have the equal Euclid distance between two paths and the higher error occurrence probability. For example, in the above patent, this condition is that the recording series have the minimum Euclid distance between two paths from branch to merge of paths.

FIG. 9 shows a distribution of metric difference calculated at the junction point of paths for the relevant recording series. Suppose that the distribution of metric difference is approximated by the normal distribution, and the mean value of the normal distribution is μ, and the standard deviation is σ. The metric difference is negative when an error occurs, or a wrong branch is selected, as previously mentioned. Thereby, the probability that the metric difference is negative is equal to the bit error rate (BER), which can be estimated by calculating the probability of a frequency distribution where the metric difference value is negative.

When it suffices to know the relative value for the quality of reproducing signal in the optical disk or optical disk unit, but not the absolute value of BER, the standard deviation value σ and the mean value μ may be employed as the indexes. When the standard deviation value σ is small and the mean value μ is close to the ideal Euclid distance, the quality of reproducing signal is more excellent.

Moreover, the quality of reproducing signal may be evaluated by the percentage of the number at or below a predetermined threshold in the frequency distribution of metric difference value.

Though the record pattern is known in the above example, when the record pattern is unknown, the quality of reproducing signal may be also evaluated by the same method. This method was disclosed in Japanese Patent Application Laid-Open No. 2003-141823. According to this patent, the statistical processing for the metric difference value |Pa−Pb|, where the metric value for the most probable path of state transition is Pa and the metric value for the secondly probable path is Pb, can be performed and assessed, thereby evaluating the quality of reproducing signal.

By the way, with the above method for evaluating the quality of generative signal in the conventional example, it is insufficient to lead the conditions for the parameters for recording/reproducing apparatus to the optimal conditions exactly in a short time, resulting in a problem that the optimal recording reproducing conditions can not be found.

In the following, this point will be described below. The amount of digital information remarkably increases, and accordingly, the development of optical disks and optical disk units that are suitable for larger capacity and higher density has been made.

Under such circumstances, the lighting form of laser pulses in the recording is complicated to decrease the influences of thermal interference occurring during the optical modulation recording. Especially in the optical disk medium which can be overwritten, the information is recorded employing the record pulse sequence having a record pulse playing a role of forming the record mark and an elimination pulse forming the non-mark that is not the record mark in the lighting of record pulse.

Since the data transfer at higher rate is demanded without regard to the overwritable medium, the optical disk drives capable of high speed recording such as double or quadruple the standard recording rate have been developed.

The condition for the quality of regenerated signal is complicated while the measures for higher line density and speed-up are taken. The formation of the record mark by recording or overwriting of the optical disk depends on the state of temperature distribution of the medium due to laser lighting at the time of recording or the transient state of the temperature distribution. When a record mark is seen, the condition is not necessarily the same between the fore end and the back end of this mark. The same can be said for the regenerated signal when this mark is regenerated, and the condition may be different between the quality of reproducing signal at the fore end of mark and the quality of reproducing signal at the back end of mark.

In the above-mentioned optical disk medium which can be overwritten, the record pulse for governing the recording and the elimination pulse which administers elimination exist in the record pulse, though they are not perfectly independent. In some cases, the signal quality may be remarkably different between the fore end of record mark and the back end of record mark.

Also, when the measure for speed-up is taken, there are some cases where the line speed at the time of recording changes, and the signal quality may be remarkably different between the fore end of record mark and the back end of record mark only by making a relative change of recording power value under the condition of normal speed due to the influence of thermal responsibility. Specially, as for the phase change media which can be overwritten, because the transient state in not only the thermal distribution but also the distribution of temperature administers the formation of the record mark, the recording terms are complicated.

Further, the processing technology of the regenerative signal advances along with the higher density in recent years, and the waveform equalization technology specially becomes the technology which is indispensable. It is important to evaluate the quality of reproducing signal in the optimization of this waveform equalization as well.

Under the conditions where the evaluation of such regenerated signal quality is important on the actual device, the conventional method not coping with a change in polarity of the regenerative signal but evaluating the quality of reproducing signal irrespective of the polarity of the regenerative signal had a problem that the parameters involved in the regenerated signal quality could not be controlled in the optimal condition exactly in a short time.

### SUMMARY OF THE INVENTION

This invention provides an information reproducing method and an information recording reproducing apparatus in which the transition of polarity of a regenerative signal, or the change of polarity in a record mark sequence, is dealt with employing an index in correlation with an error ratio of binarization result by the maximum likelihood decoding.

According to the invention, there is provided an information recording reproducing method for decoding the information with the maximum likelihood decoding, the method comprising the steps of:

detecting a recording series on a state transition path having a certain Euclid distance corresponding to a change of the polarity of record code in the recording series;

acquiring a likelihood difference between the most probable state transition path and the secondly probable state transition path from branch of state transition paths to merge of state transition paths in the detected recording series; and

conducting a statistical processing for the likelihood difference individually corresponding to the change of polarity in the recording series to evaluate the quality of reproducing signal.

Also, according to the invention, there is provided an information recording reproducing apparatus for decoding the information with the maximum likelihood decoding, the apparatus comprising:

a detection circuit for detecting a recording series on a state transition path having a certain Euclid distance corresponding to a change of the polarity of record code in the recording series;

a calculation circuit for acquiring a likelihood difference between the most probable state transition path and the secondly probable state transition path from branch of state transition paths to merge of state transition paths in the detected recording series; and

an evaluation circuit for conducting a statistical processing for the likelihood difference individually corresponding to the change of polarity in the recording series to evaluate the quality of reproducing signal.

These embodiments will be described in more detail in the following detailed description of the invention.

### BRIEF DESCRIPTION OF THE DRAWINGS

FIG. 1 is a state transition diagram according to an embodiment of the present invention;

FIG. 2 is a trellis diagram according to the embodiment of the invention;

FIGS. 3A, 3B, 3C, 3D, 3E, 3F, 3G and 3H are the trellis diagrams and the graphs of changing signal level where the Euclid distance is minimum according to the embodiment of the invention;

FIGS. 4A, 4B, 4C, 4D, 4E, 4F, 4G and 4H is the trellis diagrams and the graphs of changing signal level where the Euclid distance is minimum according to the embodiment of the invention;

FIG. 5 is a block diagram showing an optical disk unit (information recording reproducing device) according to one embodiment of the invention;

FIG. 6 is a block diagram showing one example of a Viterbi decoding circuit and a metric difference operation circuit;

FIG. 7 is a circuit diagram showing one example of a path memory of the Viterbi decoding circuit;

FIG. 8 is a block diagram showing an optical disk unit according to another embodiment of the invention; and

FIG. 9 is a graph showing an example of a metric difference distribution.

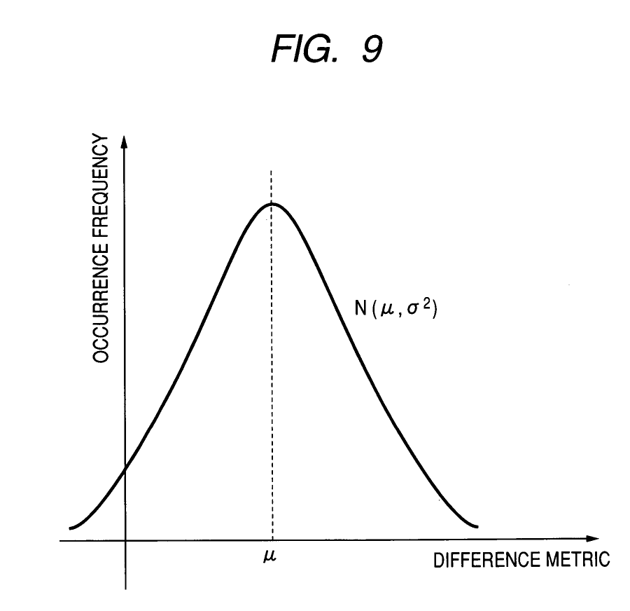

### DESCRIPTION OF THE PREFERRED EMBODIMENTS

The best mode for carrying out the present invention will be described below with reference to the accompanying drawings. In this embodiment, firstly, taking a recording series on a path having the minimum Euclid distance as an example, a process for acquiring a likelihood difference on the path of reproducing signal series corresponding to this recording series will be described below. Herein, a PRML (Partial-Response Maximum-Likelihood) method which involves recording/reproducing by a partial response method and making the maximum likelihood decoding such as Viterbi decoding will be described, in which PR(1,2,2,1) of partial response characteristic is chosen, and the minimum run length is restricted to 1, employing (Run Length Limited) code such as RLL(1,7) code.

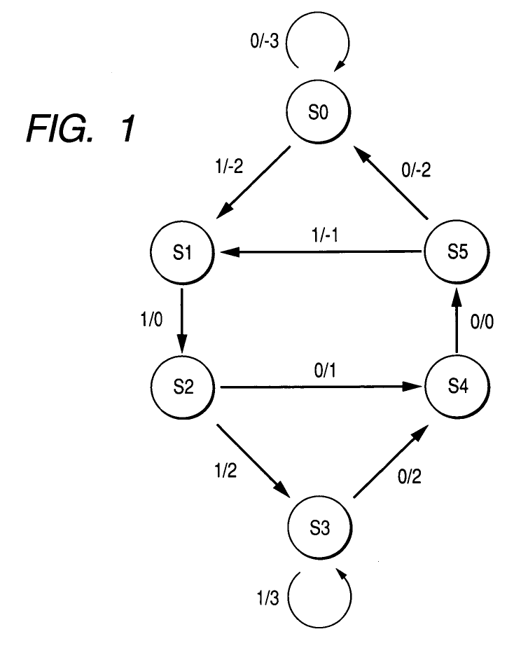

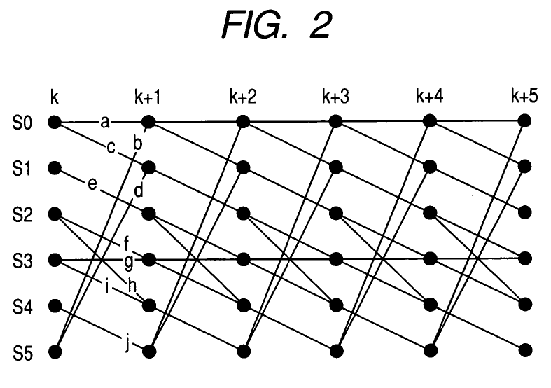

A state which depends on a record bit string b(k) ∃ (0,1) at the data distinction point k becomes any one of 6 states of S0, S1, S2, S3, S4 and S5 as shown in Table 1. Each state transits to the next state according to the value of next record bit. FIG. 1 is a state transition diagram showing the state transition at this time, and FIG. 2 is a trellis diagram. In FIG. 1 of the state transition diagram, the arrow and the input/output value of state transition are indicated. Herein, the minimum value of the regenerative signal level in the ideal waveform is shown as −3 and the maximum value as 3.

In FIG. 2 of the trellis diagram, ● mark designates a state at each data distinction point, and the line between ● marks designates a state transition by the record bit. A state transition indicated by the line is called a branch, and an identifier of the branch is assigned a character of a, b, c, d, e, f, g, h, i, j or h. The relationship of branch, the record bit strings b(k−3), b(k−2), b(k−1) and b(k), the preceding and succeeding states S(k−1) and S(k), the expected value y(k), and the branch metric value (z(k)−y(k))² is listed in Table 2.

Herein, the expected value y(k) means an output for the record bit string b(k) on the ideal regenerating channel without noise and distortion, in which the minimum value of the regenerative signal level in the ideal wave form is shown as −3 and the maximum value as 3. Where z(k) is an actual regenerated series at the data distinction point k.

The branch metric value is the quantity which indicates the difference between the actual regenerated series z(k) and the expected value y(k) of each branch, and denoted with a subscript of each branch such as bma(k), bmb(k).

Herein, the branches equivalent to the forbidden patterns { . . . 0,1,0, . . . } and { . . . 1,0,1, . . . } where the minimum run length is restricted to 1 in the state transition diagram of FIG. 1, the trellis diagram of FIG. 2 and (1-7) modulation rule in Table 2 are excluded.

As for the Viterbi decoding, the branches (a, b), (c,d), (f,g) and (h,i) which join in the states S0, S1, S3 and S4 as shown in FIG. 2 are chosen at each data distinction point. The branches e and j are left unselected in the states S2, S5. As a result, the recording series equivalent to the path of one continuation left without interruption is detected as an actually recorded series.

The metric values mSx(k) for selection of the path and each state at this time are represented by the following Formula (1) by using the expression of branch metric value in Table 2.
mS0(k)=min{mS0(k−1)+bma(k),mS5(k−1)+bmb(k)}
mS1(k)=min{mS0(k−1)+bmc(k),mS5(k−1)+bmd(k)}
mS2(k)=mS1(k−1)
mS3(k)=min{mS2(k−1)+bmf(k),mS3(k−1)+bmg(k)}
mS4(k)=min{mS2(k−1)+bmh(k),mS3(k−1)+bmi(k)}
mS5(k)=mS4(k−1)
Where min{xxx,zzz} is the function of selecting the smaller value of xxx and zzz.

Herein, the metric value mS0(k−1) is the accumulated value of branch metric on the path left in the state S0 at the data distinction point k−1. At the data distinction point k, the branch a or b having smaller metric is chosen, and that value is made mS0(k) and employed for selection at the next data distinction point k+1. As for the states S1, S3 and S4 as well, the same processing is done. The states S2 and S5 inherit the metric value of states S1, S4 as shown in the trellis diagram of FIG. 2, without selection, due to restriction on the (1-7) minimum run length.

The metric value when the path equivalent to the true recording series of N bits is chosen without mistake is represented by the following Formula (2).
mSx(k)=Σ(z(k)−y(k)², (k=0, 1, . . . , N−1) Formula (2)
Where y(k) is the true expected value sequence corresponding to the true recording series. An N-dimensional vector {y(k)} is equivalent to the Euclid distance to the actual input vector {z(k)}.

Since the metric value of the surviving path may be made the smallest in the above selection, mSx(k) is minimum value. Therefore, the path having the shortest distance to the recording series vector survives. This is clear from the Formula (2) that it is zero, if the actual regenerated series z(k) is matched with the true expected value sequence y(k) equivalent to the true recording series, or takes the positive value of non-zero if there is any one which is unmatched.

The junction point of paths in a certain state S, and the metric value from branch to merge of paths are noted. Since the metric value in each state is equivalent to Euclid distance between the actual input vector {z(k)} and the true expected value sequence {y(k)} as above mentioned, when any of the paths takes all the ideal values, the metric value of the path which takes the ideal values becomes “0”, and the metric value of the other path after the branch just before joining becomes the value of Euclid distance to the true path. Therefore, the absolute value of the difference in metric value becomes Euclid distance between two paths. When the relations are contrary, the metric value is reversed, giving rise to a similar result. Also, when the metric values on both paths are equal, it is difficult to choose either path, in which the absolute value of the difference in metric value at this time becomes 0. Furthermore, when the sample value at the data distinction point does not exist between changing levels on both paths, the absolute value of the difference in metric value takes a bigger value than both the Euclid distance values.

Accordingly, the absolute value of the difference in metric value from branch to merge of paths becomes a distribution that includes the Euclid distance between them, whereby the signal quality can be evaluated to choose the path whose reliability is higher as this absolute value is closer to the Euclid distance between both paths, and to choose the path whose reliability is lower as it is farther away from the Euclid distance.

Also, the difference in metric value from branch to merge of the paths can be used as an index to know the probability from branch to merge of the paths, because the accumulated value of the metric value before the branch point of the paths can be ignored.

To suitably utilize the absolute value of the difference in metric value from branch to merge of the paths as the index of the regenerated signal quality, the quality of regenerated signal can be evaluated more efficiently if the pattern of the state transition whose wrong possibility is big is detected. Thereby, even if all the patterns of the state transitions are not detected, the index in correlation with the error rate can be obtained.

In this embodiment, the paths from branch to merge are 10, 12 and 36 in the Euclid distance, which means the error of two or more bits when the Euclid distance is 12 or 36, or the error of one bit when the Euclid distance is 10.

For example, when the Euclid distance is 12, the change of the state transition from branch to merge of paths may be {S3→S3→S4→S5→S1→S2→S3, S3→S4→S5→S1→S2→S3→S3}, in which the record pattern sequence becomes (111100111, 111001111) at this time, causing a two-bit error in which there is difference at the fourth bit and the sixth bit.

As another example in which the Euclid distance is 36, the change of the state transition from branch to merge of paths may be {S0→S0→S0→S0→S0→S0, S0→S1→S2→S4→S5→S0}, in which the record pattern sequence becomes (00000000, 00011000) at this time, causing a two-bit error in which there is difference at the fourth bit and the fifth bit.

Herein, the state transition pattern whose wrong possibility is big is the state transition pattern that the absolute value of the metric difference becomes small, which means the pattern in which the Euclid distance from branch to merge of the paths becomes the minimum. If white noise in the noise contained in the regenerative signal is dominant, it is expected that the error frequency of the pattern in which the Euclid distance becomes 10 increases. Actually, if the error pattern after the PRML processing is analyzed, the error rate of the regenerative signal can be estimated suitably by applying the metric difference of the record pattern in which the Euclid distance becomes 10 as an evaluation index of the quality of reproducing signal, because of mostly a shift error of one bit.

Eight combinations of the relevant state transitions exist in this embodiment. Table 3 lists the combinations of the record pattern sequence at this time. In Table 3, the combinations of state transition (A,B), (C,D), (E,F), (G,H), (I,J), (K,L), (M,N) and (O,P) are combinations of record pattern in which the Euclid distance is 10.

TABLE 3

| State transition | | | | | Record bit | Path |
|---|---|---|---|---|---|---|
| S(k-4) | S(k-3) | S(k-2) | S(k-1) | S(k) | string | Pattern |
| S0 | S0 | S1 | S2 | S3 | 0000111 | A |
| S0 | S1 | S2 | S3 | S3 | 0001111 | B |
| S0 | S0 | S1 | S2 | S4 | 0000110 | C |
| S0 | S1 | S2 | S3 | S4 | 0001110 | D |
| S2 | S3 | S4 | S5 | S0 | 0111000 | E |
| S2 | S4 | S5 | S0 | S0 | 0110000 | F |
| S2 | S3 | S4 | S5 | S1 | 0111001 | G |
| S2 | S4 | S5 | S0 | S1 | 0110001 | H |
| S3 | S3 | S4 | S5 | S0 | 1111000 | I |
| S3 | S4 | S5 | S0 | S0 | 1110000 | J |
| S3 | S3 | S4 | S5 | S1 | 1111001 | K |
| S3 | S4 | S5 | S0 | S1 | 1110001 | L |
| S5 | S0 | S1 | S2 | S3 | 1000111 | M |
| S5 | S1 | S2 | S3 | S3 | 1001111 | N |
| S5 | S0 | S1 | S2 | S4 | 1000110 | O |
| S5 | S1 | S2 | S3 | S4 | 1001110 | P |

In this way, the quality of reproducing signal can be evaluated by detecting the patterns taking predetermined state transitions from branch to merge of paths, and employing the standard deviation σ and the mean value μ in the distribution of the absolute value of a metric difference in the detected state transitions as the evaluation index.

In this embodiment, a calculation/evaluation process for metric difference is made by noting the change of the polarity of the record bit in the combination of record patterns, as described below.

Table 3 lists the combinations of state transitions in which the Euclid distance is the minimum, and the record bit patterns at this time. In Table 3, the combinations of (A,B), (C,D), (E,F), (G,H), (I,J), (K,L), (M,N) and (O,P) are the record patterns in which the Euclid distance is 10. As indicated in Table 3, these combinations are different in the record bit by one bit.

Further, among these combinations of the record patterns, four combinations of {(A,B) and (I,J)}, {(C,D) and (K,L)}, {(E,F) and (M,N)} and {(G,H) and (O,P)} are in the relation where “0” and “1” in the record bit sequence are reversed.

In other words, these combinations indicate the difference whether one bit error occurs in changing from “0” to “1”, or from “1” to “0”.

Herein, classifying the combinations according to whether one bit error occurs in changing from “0” to “1”, or from “1” to “0”, the patterns in which one bit error occurs in changing from “0” to “1” are {(A,B),(C,D),(M,N),(O,P)}, and the patterns in which one bit error occurs in changing from “1” to “0” are {(E,F),(G,H),(I,J),(K,L)}.

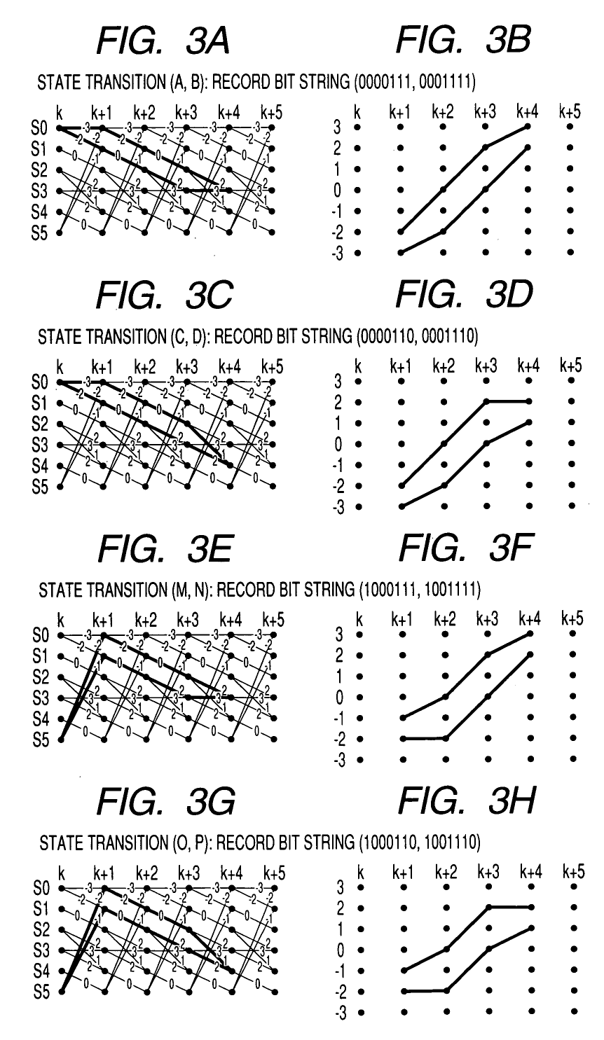

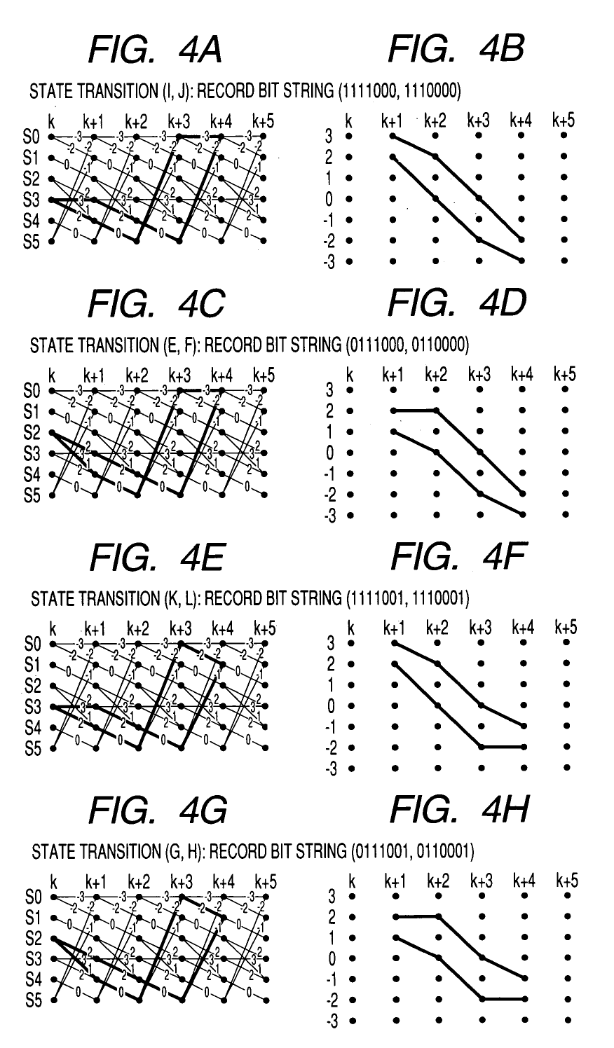

FIGS. 3A to 3H and 4A to 4H show the state transitions in the trellis diagram for these patterns and the changes of signal level in the ideal state at the time of state transition. In FIGS. 3A to 3H and 4A to 4H, the combination pattern (e.g., (A,B)) of the state transition and the record bit sequence at that time are shown at the upper stage of the trellis diagram. The numerical value on each path in the trellis diagram indicates the ideal level in the state transition. The path drawn by the bold line in the trellis diagram shows the combination pattern of state transitions in the trellis diagram, and the change of ideal level corresponding to the state transition is shown on the right.

In FIGS. 3A to 3H and 4A to 4H, in the patterns {(A,B),(C,D),(M,N),(O,P)} in which one bit error occurs in changing from “0” to “1” corresponding to the change of record bit, as indicated in the change in signal level, the polarity of change in the regenerative signal level corresponds to the rising polarity in this example, while in the patterns {(E,F),(G,H),(I,J), (K,L)} in which one bit error occurs in changing from “1” to “0”, the polarity of change in the regenerative signal level corresponds to the falling polarity.

Utilizing the above features, the relevant record bit sequences for calculating the metric difference are grouped according to the change of polarity of the record bit, supposing the occurrence of bit error in this embodiment. For each group, the metric difference is calculated, and the quality of reproducing signal can be evaluated for each change of polarity of the record bit, employing the standard deviation ν, mean value μ and so on in the distribution of the absolute value of metric difference as the evaluation index.

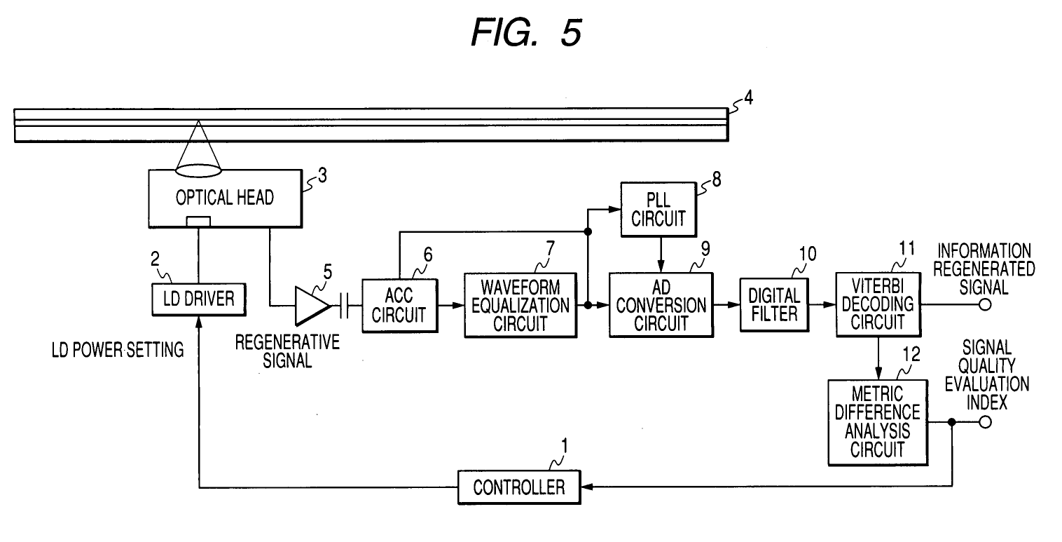

Referring to FIG. 5, an optical disk unit for decoding the regenerative signal by the PRML method will be described below. FIG. 5 is a block diagram showing the configuration of an optical disk unit according to one embodiment of the invention. In FIG. 5, first of all, a regenerative signal read from an optical disk 4 by an optical head 3 is amplified by a preamplifier 5, AC coupled with low frequency component removed, and then inputted into an AGC (Automatic Gain Controller) circuit 6. In the AGC circuit 6, the gain is adjusted so that the output of a waveform equalization circuit 7 at the latter stage may be at a predetermined amplitude. The regenerative signal outputted from the AGC circuit 6 has the waveform equalized by the waveform equalization circuit 7. The regenerative signal with equalized waveform is outputted to a PLL circuit 8 and an A/D converter 9.

The PLL circuit 8 generates a regenerative clock synchronizing with the regenerative signal. The A/D conversion circuit 9 samples the regenerative signal in synchronism with the regenerative clock outputted from the PLL circuit 8. The sampling data obtained in this way is outputted from the A/D conversion circuit 9 to a digital filter 10.

The digital filter 10 has the frequency characteristic set such that the frequency characteristic of a recording/reproducing system may become the characteristic (PR(1,2,2,1) equalization characteristic in this embodiment) supposed by a Viterbi decoding circuit 11. Though in this embodiment, the waveform equalization circuit 7 and the digital filter 10 are provided separately, it is unnecessary that both the functions are specifically separated, but may be constructed by the same filter. In this embodiment, because the PLL circuit 8 is in analog configuration, they are separately denoted. Also, in the case where a waveform equalization state for leading the PLL and a waveform equalization state for regenerating the signal are separately provided, the individual equalization circuits are needed as shown in this embodiment.

The data outputted from this digital filter 10 is inputted into a Viterbi decoding circuit 11 which performs the maximum likelihood decoding. The Viterbi decoding circuit 11 decodes the signal equalized by PR(1,2,2,1) in accordance with the maximum likelihood decoding method to output the binary data.

Also, the decoded binary data and the calculation result (branch metric) of Euclid distance at every time are outputted from the Viterbi decoding circuit 11 to a metric difference analysis circuit 12. The metric difference analysis circuit 12 discriminates the state transition from the binary data obtained from the Viterbi decoding circuit 11 and acquires a metric difference value indicating the reliability of decoded result in terms of this discrimination result and the branch metric. Thereby, the error ratio of decoded result can be estimated.

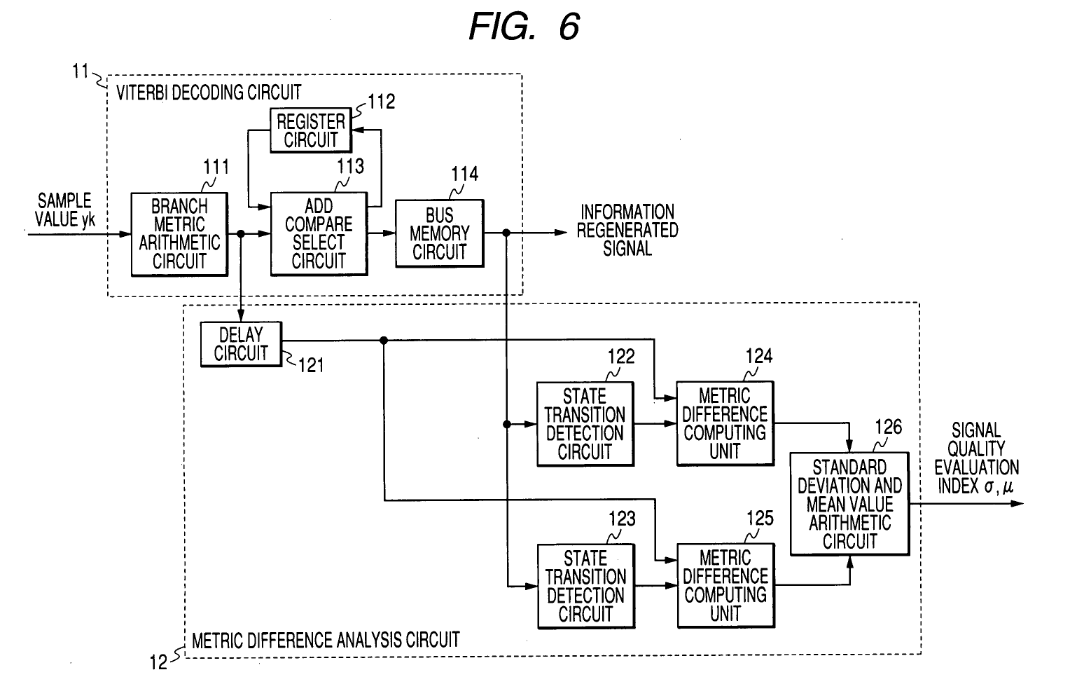

Referring to FIG. 6, the Viterbi decoding circuit 11 and the metric difference analysis circuit 12 will be described below in detail. FIG. 6 is a block diagram showing the configuration of the Viterbi decoding circuit 11 and the metric difference analysis circuit 12. A sample value y(k) outputted from the digital filter 10 is inputted into a branch metric arithmetic circuit 111 of the Viterbi decoding circuit 11. The branch metric arithmetic circuit 111 computes the branch metric equivalent to the distance between the sample value y(k) and the expected value z(k). Because the PR(1,2,2,1) equalization is employed, the expected value z(k) has seven values ranging from −3 to 3. The branch metric value indicating the distance between expected value z(k) and sample value y(k) at the data distinction point k is represented corresponding to each state transition as listed in Table 2.

The computed branch metric is inputted into an addition/comparison/selection circuit (Add-Compare-Select circuit: ACS circuit) 113. The certainty of each state S0 to S5 at the data distinction point k is obtained from the input branch metric at the data distinction point k and the metric value of each state at the data distinction point k−1.

The metric value of each state is represented by Formula (3).
mS0(k)=min{mS0(k−1)+bma(k),mS5(k−1)+bmb(k)}
mS1(k)=min{mS0(k−1)+bmc(k),mS5(k−1)+bmd(k)}
mS2(k)=mS1(k−1)
mS3(k)=min{mS2(k−1)+bmf(k),mS3(k−1)+bmg(k)}
mS4(k)=min{mS2(k−1)+bmh(k),mS3(k−1)+bmi(k)}
mS5(k)=mS4(k−1) Formula (3)
Where min{xxx,zzz} is the function of choosing the smaller value of xxx and zzz.

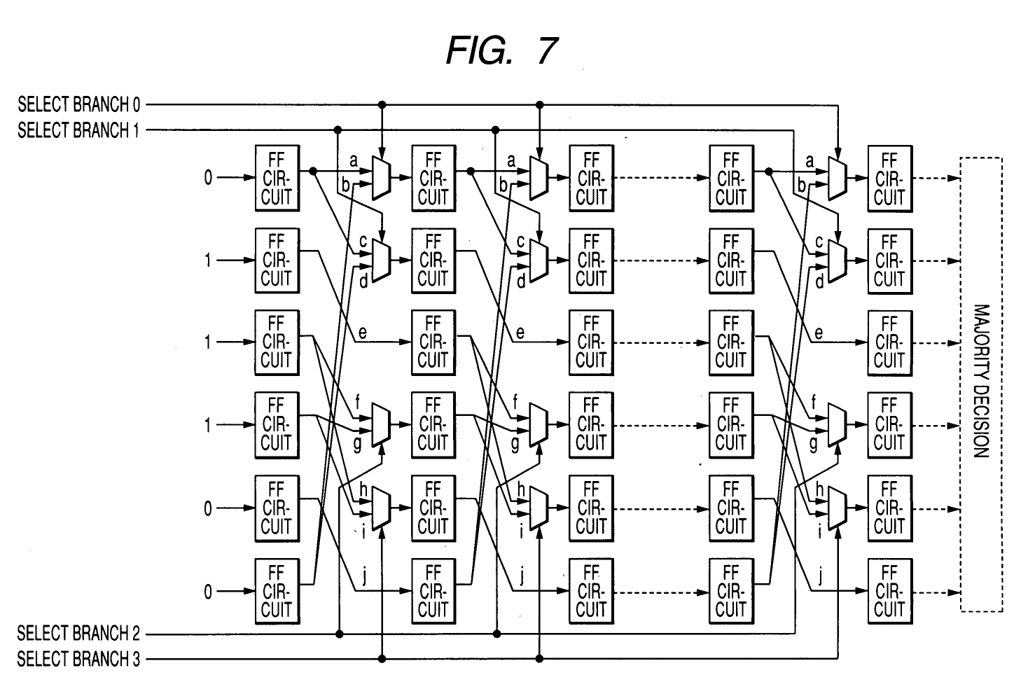

The metric values mS0(k) to mS5(k) at the data distinction point k are stored in a register circuit 112, and employed to calculate the metric value of each state at the next data distinction point k+1. Also, an ACS circuit 113 selects the state transition in which the metric value is the minimum in accordance with the Formula (3), and outputs a control signal SelectBranch0 to SelectBranch3 based on the selection result as shown in Formula (5) to a path memory circuit 114 having the circuit configuration as shown in FIG. 7.
IF {mS0(k−1)+bma(k)≧mS5(k−1)+bmb(k)} then SelectBranch0=‘b’ else SelectBranch0=‘a’
IF {mS0(k−1)+bmc(k)≧mS5(k−1)+bmd(k)} then SelectBranch1=‘d’ else SelectBranch1=‘c’
IF {mS3(k−1)+bmf(k)≧mS2(k−1)+bmg(k)} then SelectBranch2=‘g’ else SelectBranch2=‘f’
IF {mS3(k−1)+bmi(k)≧mS3(k−1)+bmj(k)} then SelectBranch3=‘j’ else SelectBranch3=‘i’ Formula (4)

The path memory circuit 114 outputs a bit string equivalent to the most probable state transition sequence according to the state transition rule from the memory end, based on an input control signal, and outputs the binary data corresponding to the state transition sequence estimated by making majority decision for the output from this memory end.

On the other hand, to evaluate the quality of reproducing signal, the branch metric outputted from the branch metric arithmetic circuit 111 is inputted into a delay circuit 121, delayed by a signal processing time in the addition/comparison/selection circuit 113 and the path memory circuit 114, and outputted to the metric difference operation units 124, 125. Also, the binary data outputted from the path memory 114 is inputted into the state transition detection circuits 122, 123 to detect a predetermined pattern of binary data.

More specifically, the data patterns (A,B), (C,D), (M,N), (O,P), (E,F), (G,H), (I,J) and (K,L) corresponding to eight state transitions as listed in the Table 3 are detected, in which the state transition detection circuit 122 detects {(A,B), (C,D), (M,N), (O,P)}, and the state transition detection circuit 123 detects {(E,F), (G,H), (I,J), (K,L)} individually.

The metric difference operation units 124, 125 calculate the absolute values Δm01, Δm10 of metric difference between the state transitions detected in accordance with the Formula (5) (metric difference between the most probable state transition path and the secondly most probable state transition path from the branch of state transition paths to the merge of state transition paths in the detected data pattern), when the state transition detection circuits 122, 123 detect a predetermined state transition. Herein, the metric difference Δm01 is the absolute value of metric difference when the change of record bit string, which is supposed a bit shift error, is from “0” to “1”, and the metric difference Δm10 is the absolute value of metric difference when the change of record bit string, which is supposed a bit shift error, is from “1” to “0”.

Detection pattern: at (000×111)
Δm01=|(bma(k−3)+bmc(k−2)+bme(k−1)+bmf(k))−(bmc(k−3)+bme(k−2)+bmf(k−1)+bmg(k))|

Detection pattern: at (000×110)
Δm01=|(bma(k−3)+bmc(k−2)+bme(k−1)+bmh(k))−(bmc(k−3)+bme(k−2)+bmf(k−1)+bmi(k))|

Detection pattern: at (100×111)
Δm01=|(bmb(k−3)+bmc(k−2)+bme(k−1)+bmf(k))−(bmd(k−3)+bme(k−2)+bmf(k−1)+bmg(k))|

Detection pattern: at (100×110)
Δm01=|(bmb(k−3)+bmc(k−2)+bme(k−1)+bmh(k))−(bmc(k−3)+bme(k−2)+bmf(k−1)+bmi(k))|

Detection pattern: at (011×000)
Δm10=|(bmf(k−3)+bmi(k−2)+bmj(k−1)+bmb(k))−(bmh(k−3)+bmj(k−2)+bmb(k−1)+bma(k))|
Detection pattern: at (011×001)
Δm10=|(bmf(k−3)+bmi(k−2)+bmj(k−1)+bmd(k))−(bmh(k−3)+bmj(k−2)+bmb(k−1)+bmc(k))|

Detection pattern: at (111×000)
Δm10=|(bmg(k−3)+bmi(k−2)+bmj(k−1)+bmb(k))−(bmi(k−3)+bmj(k−2)+bmb(k−1)+bma(k))|

Detection pattern: at (111×001)
Δm10=|(bmg(k−3)+bmi(k−2)+bmj(k−1)+bmd(k))−(bmi(k−3)+bmj(k−2)+bmb(k−1)+bmc(k))|

For a certain state transition detected in this manner, the values of Δm01 and Δm10 calculated as above are inputted into a standard deviation mean value arithmetic unit 126. The standard deviation mean value arithmetic unit 126 calculates the mean values and the standard deviations for the distributions of inputs Δm01 and Δm10, and outputs two values, that is, the mean values μ01 , μ10 and standard deviations σ01, σ10 for Δm01 and Δm10. The mean values μ01, μ10 and standard deviations σ01, σ10 outputted here are in the predetermined state transition in which the Euclid distance between two paths is the minimum value as described above.

Also, the standard deviation mean value arithmetic unit 126 treats Δm01 and Δm10 as the same metric difference value, and performs the same operation for calculating the mean value μ and the standard deviation σ. Thereby, the signal quality is simply evaluated using the metric difference value that is not dependent upon the signal polarity of record bit, whereby the signal quality evaluation at higher level can be made by obtaining the mean value μ and the standard deviation σ, together with the mean values μ01, μ10 and the standard deviations σ01, σ10 which are obtained from the metric difference values dependent upon the polarity.

Employing these mean values and the standard deviations, the evaluation for relative signal quality dependent upon the parameters is enabled, and the error ratio of regenerative signal can be estimated from a general error function erfc. In this embodiment, the error ratio of regenerative signal can be estimated corresponding to the polarity change of record bit.

Also, the quality of reproducing signal can be evaluated by obtaining not only the standard deviation and the mean value but also the frequency ratio at or below a predetermined threshold in the distribution of metric difference. In this case, the standard deviation mean value arithmetic circuit 126 may be provided with this function.

As described above, the quality of reproducing signal for each polarity can be evaluated including the polarity change of record bit, employing the standard deviations σ01, σ10 and the mean values μ01, μ10 in the distributions of Δm01 and Δm10 outputted from the metric difference analysis circuit 12.

The metric difference value may be also calculated by a calculation method including no square operation, as described below.

Since the metric value is generally discussed as the relative value of length, but not the absolute value, there is no trouble by making addition, subtraction, multiplication or division of a fixed value. Accordingly, when the formula of branch metric value as shown in Table 2 is expanded, and divided by the common term z(k)² of branch metric values, it is possible to calculate the branch metric value only with the first order term of the sample value z(k).

Moreover, the method for calculating the metric difference value corresponding to the polarity of record bit in this embodiment is appropriate for the control of improving the quality of reproducing signal based on the indexes (standard deviations σ01 , σ10 and the mean values μ01, μ10).

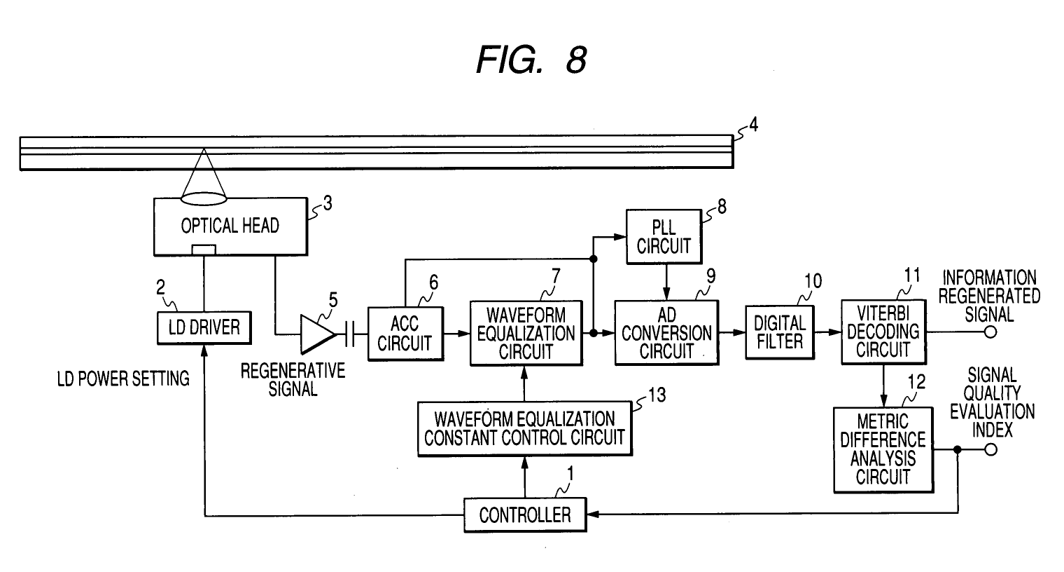

For example, the quality of reproducing signal may be improved by changing the waveform equalization constant of the waveform equalization circuit 7 via a controller 1, so that the mean value outputted from the metric difference analysis circuit 12 may be the ideal value, or the standard deviation may be minimum, employing a waveform equalization constant control circuit 13 as shown in FIG. 8.

At this time, since the evaluation index with the metric difference corresponding to the polarity change of record bit string, or the polarity change of regenerative signal, can be evaluated individually in this embodiment, the equalization constant of the waveform equalization circuit can be set up while monitoring the evaluation index value to optimize the states of rising polarity and falling polarity of the regenerative signal. Accordingly, even when the optimal equalization constants of the waveform equalization circuit are asymmetrical, the equalization constants can be set up efficiently. The configuration of FIG. 8 is the same as that of FIG. 5, except that the waveform equalization constant control circuit 13 is provided.

Also, in the optical disk unit that can record the information, the recording power or record compensation amount is controlled so that the mean value outputted from the metric difference analysis circuit 12 may be the ideal value, or the standard deviation may be minimum, whereby the recording parameters are optimized via the controller 1.

In this case, since it is possible to evaluate individually the evaluation index with the metric difference corresponding to the polarity change of record bit string, or the polarity change of regenerative signal in this embodiment, the recording power can be set up to optimize the states of rising polarity and falling polarity of the regenerative signal, while monitoring the evaluation index value. Especially in recent years, the record pulses are diversified, and the record pulse sequence or the corresponding recording power is set to prevent asymmetry in the regenerative signal or a jitter characteristic difference in the rising or falling of the regenerative signal, whereby the recording media that can be overwritten is required to have the high control precision.

Under such circumstances, if the rising/falling signal quality of reproducing signal can be evaluated individually, it is possible to control the parameters highly contributing to the evaluation result, for example, pulse power chiefly acting on the rising regenerative signal in the record pulse sequence, based on the evaluation result, more effectively and more efficiently.

Such control of the recording power corresponding to the polarity of regenerative signal becomes an effective method or means, especially when the thermal responsibility is changed because the line speed of recording is increased to improve the transfer rate.

Moreover, for the items adopted in the embodiment, as well as various kinds of parameters affecting the characteristics of optical disk, the signal quality can be evaluated corresponding to the polarity change of record bit sequence, or the polarity change of regenerative signal, whereby various kinds of parameters can be controlled via the controller 1 efficiently.

This application claims priority from Japanese Patent Application No. 2004-147855 filed on May 18, 2004, which is hereby incorporated by reference herein.

What is claimed is:

1. An information recording reproducing method for decoding the information with the maximum likelihood decoding, the method comprising the steps of:
detecting a recording series on a state transition path having a certain Euclid distance corresponding to a change of the polarity of record code in said recording series;
acquiring a likelihood difference between the most probable state transition path and the secondly probable state transition path from branch of state transition paths to merge of state transition paths in said detected recording series; and
conducting a statistical processing for said likelihood difference individually corresponding to the change of polarity in said recording series to evaluate the quality of reproducing signal.

2. The information recording reproducing method according to claim 1, wherein said certain Euclid distance is the minimum Euclid distance in the reproducing signal series.

3. The information recording reproducing method according to claim 1, wherein the quality of reproducing signal by said statistical processing is evaluated based on the standard deviation value in a frequency distribution of the likelihood difference of path.

4. The information recording reproducing method according to claim 1, wherein the quality of reproducing signal by said statistical processing is evaluated based on the percentage of the number at or below a predetermined threshold in the frequency distribution of the likelihood difference of path.

5. The information recording reproducing method according to claim 1, wherein the quality of reproducing signal by said statistical processing is evaluated based on the mean value in the frequency distribution of the likelihood difference of path.

6. The information recording reproducing method according to claim 1, further comprising changing the conditions concerning the recording or reproduction based on the evaluation result of said quality of reproducing signal.

7. An information recording reproducing apparatus for decoding the information with the maximum likelihood decoding, the apparatus comprising:
a detection circuit for detecting a recording series on a state transition path having a certain Euclid distance corresponding to a change of the polarity of record code in said recording series;
a calculation circuit for acquiring a likelihood difference between the most probable state transition path and the secondly probable state transition path from branch of state transition paths to merge of state transition paths in said detected recording series; and
an evaluation circuit for conducting a statistical processing for said likelihood difference individually corresponding to the change of polarity in said recording series to evaluate the quality of reproducing signal.

8. The information recording reproducing apparatus according to claim 7, wherein said certain Euclid distance is the minimum Euclid distance in the reproducing signal series.

9. The information recording reproducing apparatus according to claim 7, wherein the quality of reproducing signal by said statistical processing is evaluated based on the standard deviation value in a frequency distribution of the likelihood difference of path.

10. The information recording reproducing apparatus according to claim 7, wherein the quality of reproducing signal by said statistical processing is evaluated based on the percentage of the number at or below a predetermined threshold in the frequency distribution of the likelihood difference of path.

11. The information recording reproducing apparatus according to claim 7, wherein the quality of reproducing signal by said statistical processing is evaluated based on the mean value in the frequency distribution of the likelihood difference of path.

12. The information recording reproducing apparatus according to claim 7, further comprising a change circuit for changing the conditions concerning the recording or reproduction based on the evaluation result of said quality of reproducing signal.

13. The information recording reproducing apparatus according to claim 12, wherein said reproduction condition is an equalization constant of a waveform equalizer in the regenerative signal processing.

14. The information recording reproducing apparatus according to claim 12, wherein said information recording reproducing apparatus is an optical disk recording reproducing unit and said recording condition is a power value in the record pulse sequence.
